(19) United States
(12) Patent Application Publication
(10) Pub. No.: US 2026/0088060 A1
(43) Pub. Date: Mar. 26, 2026

(54) SEMICONDUCTOR DEVICE

(71) Applicant: Kioxia Corporation, Tokyo (JP)

(72) Inventor: Akifumi GAWASE, Kuwana (JP)

(73) Assignee: Kioxia Corporation, Tokyo (JP)

(21) Appl. No.: 19/075,001

(22) Filed: Mar. 10, 2025

(30) Foreign Application Priority Data
Sep. 20, 2024 (JP) 2024-163312

(51) Int. Cl. G11C 5/06; H10B 51/10; H10B 51/30; H10B 53/10; H10B 53/30; H10D 64/66

(52) U.S. Cl. CPC G11C 5/063; H10B 51/10; H10B 51/30; H10B 53/10; H10B 53/30; H10D 64/665

(57) ABSTRACT

A semiconductor device includes a substrate, an oxide semiconductor layer that is spaced from the substrate and contains a first metal element and oxygen (O), a first wiring opposed to the oxide semiconductor layer, a gate insulating film disposed between the oxide semiconductor layer and the first wiring, a first conductive layer that is in contact with the oxide semiconductor layer and contains a second metal element and oxygen (O), a second wiring connected to the first conductive layer, and a first insulating portion in contact with the second wiring. The first insulating portion includes a first region and a second region between the first region and the second wiring. A concentration of the first metal element or the second metal element in the second region is higher than a concentration of the first metal element or the second metal element in the first region.

### CROSS-REFERENCE TO RELATED APPLICATIONS

This application is based upon and claims the benefit of Japanese Patent Application No. 2024-163312, filed on Sep. 20, 2024, the entire contents of which are incorporated herein by reference.

### BACKGROUND

### Field

Embodiments described herein relate generally to a semiconductor device.

### Description of the Related Art

There has been known a semiconductor device including an oxide semiconductor layer, a first wiring opposed to the oxide semiconductor layer, and a gate insulating film disposed between the oxide semiconductor layer and the first wiring.

### BRIEF DESCRIPTION OF THE DRAWINGS

FIG. 1 is a schematic circuit diagram illustrating a part of a configuration of a semiconductor device according to a first embodiment;

FIG. 2 is a schematic cross-sectional view illustrating a part of the configuration of the semiconductor device;

FIG. 3 is a schematic cross-sectional view illustrating a part of the configuration of the semiconductor device;

FIG. 4 is a schematic plan view illustrating a part of the configuration of the semiconductor device;

FIG. 5 is a schematic plan view illustrating a part of the configuration of the semiconductor device;

FIG. 6 is a schematic plan view illustrating a part of the configuration of the semiconductor device;

FIG. 7 is a drawing for describing a metal element concentration distribution of a part of the configuration of the semiconductor device;

FIG. 8 is a schematic cross-sectional view for describing a method of manufacturing the semiconductor device;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view illustrating a part of a configuration of a modification of the semiconductor device according to the first embodiment;

FIG. 20 is a drawing for describing a metal element concentration distribution of a part of the configuration of the modification;

FIG. 21 is a schematic cross-sectional view for describing a method of manufacturing a semiconductor device according to a second embodiment;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view illustrating a part of a configuration of a semiconductor device according to a third embodiment;

FIG. 27 is a schematic plan view illustrating a part of the configuration of the semiconductor device;

FIG. 28 is a schematic cross-sectional view for describing a method of manufacturing the semiconductor device;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view for describing the manufacturing method;

FIG. 33 is a schematic cross-sectional view for describing the manufacturing method;

FIG. 34 is a schematic cross-sectional view for describing the manufacturing method;

FIG. 35 is a schematic cross-sectional view for describing the manufacturing method;

FIG. 36 is a schematic cross-sectional view illustrating a part of a configuration of a semiconductor device according to a fourth embodiment;

FIG. 37 is a schematic cross-sectional view for describing a method of manufacturing the semiconductor device;

FIG. 38 is a schematic cross-sectional view for describing the manufacturing method;

FIG. 39 is a schematic cross-sectional view for describing the manufacturing method;

FIG. 40 is a schematic cross-sectional view for describing the manufacturing method;

FIG. 41 is a schematic cross-sectional view for describing the manufacturing method; and

FIG. 42 is a schematic cross-sectional view for describing the manufacturing method.

### DETAILED DESCRIPTION

A semiconductor device according to one embodiment includes a substrate, an oxide semiconductor layer that is spaced from the substrate in a first direction intersecting with a surface of the substrate and contains a first metal element and oxygen (O), a first wiring opposed to a part of the oxide semiconductor layer, a gate insulating film disposed between the oxide semiconductor layer and the first wiring, a first conductive layer that is in contact with one end in the first direction of the oxide semiconductor layer and contains a second metal element and oxygen (O), a second wiring electrically connected to the first conductive layer, and a first insulating portion in contact with the second wiring. The first insulating portion includes a first region and a second region between the first region and the second wiring. A concentration of the first metal element in the second region is higher than a concentration of the first metal element in the first region, or a concentration of the second metal element in the second region is higher than a concentration of the second metal element in the first region.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

### First Embodiment

### Circuit Configuration

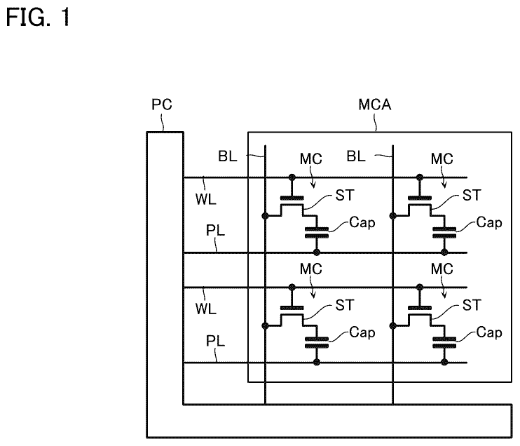

A semiconductor device according to the first embodiment includes, for example, a memory cell array MCA and a peripheral circuit PC as illustrated in FIG. 1.

The memory cell array MCA includes a plurality of bit lines BL, a plurality of word lines WL, a plurality of plate lines PL, and a plurality of memory cells MC that are connected to the plurality of bit lines BL, the plurality of word lines WL, and the plurality of plate lines PL. A plurality of memory cells MC connected to one word line WL are connected to the respective mutually different bit lines BL. A plurality of memory cells MC connected to one bit line BL are connected to the respective mutually different word lines WL.

Each of the memory cells MC includes a select transistor ST and a capacitor Cap that are connected in series between the bit line BL and the plate line PL.

The select transistor ST is a field-effect type transistor including a semiconductor layer that functions as a channel region, a gate insulating film, and a gate electrode. Each gate electrode of the select transistor ST is connected to the word line WL.

The capacitor Cap is a capacitor that includes a pair of electrodes and an insulating film. The capacitor Cap includes a memory portion.

The peripheral circuit PC includes, for example, a voltage generation circuit that generates an operating voltage and outputs the operating voltage to a voltage supply line, a decode circuit that electrically conducts a desired voltage supply line to each of the wirings (the bit lines BL, the word lines WL, and the plate lines PL) in the memory cell array MCA, a sense amplifier circuit that senses a current or a voltage of the bit lines BL, and the like.

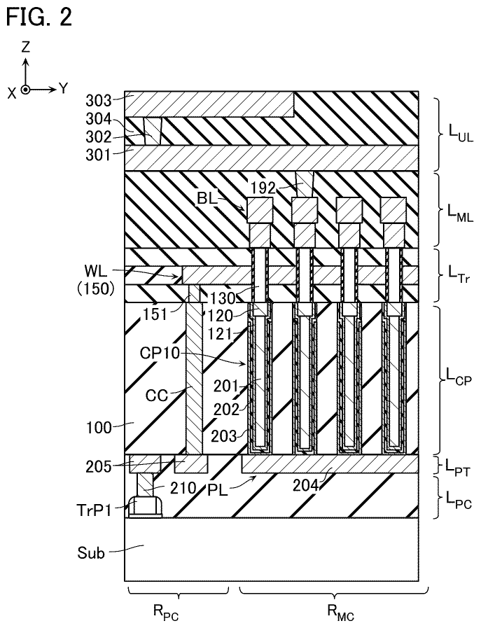

FIG. 2 is a schematic cross-sectional view illustrating a part of a configuration of the semiconductor device. As illustrated in FIG. 2, the semiconductor device according to the first embodiment includes a substrate Sub, a transistor layer L_{Tr} spaced from the substrate Sub in the Z-direction, a wiring layer L_{ML} disposed above the transistor layer L_{Tr}, a wiring layer L_{UL} disposed above the wiring layer L_{ML}, a capacitor layer L_{CP} disposed below the transistor layer L_{Tr}, a plate line layer L_{PT} disposed below the capacitor layer L_{CP}, and a peripheral circuit layer L_{PC} disposed on the substrate Sub below the plate line layer L_{PT}. The substrate Sub contains, for example, P-type silicon (Si) containing P-type impurities, such as boron (B).

As illustrated in FIG. 2, the semiconductor device according to the first embodiment includes a memory region R_{MC} and a peripheral region R_{PC} which are provided on the substrate Sub.

### Structure of Memory Region R_{MC}

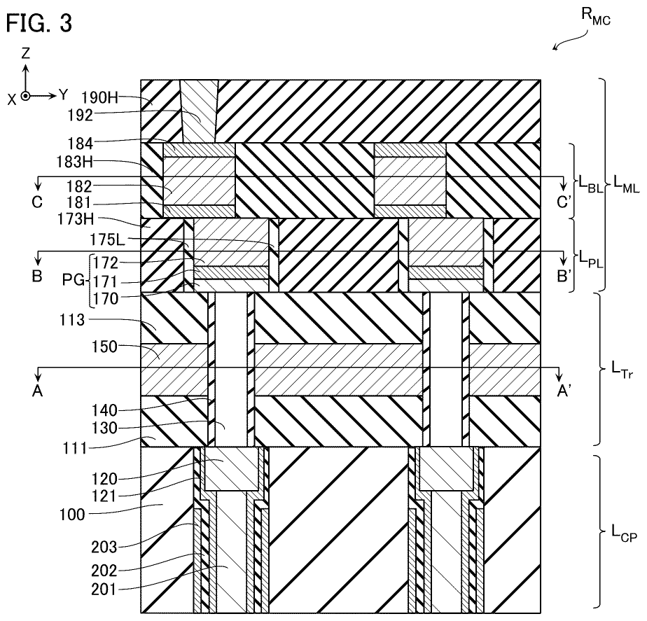

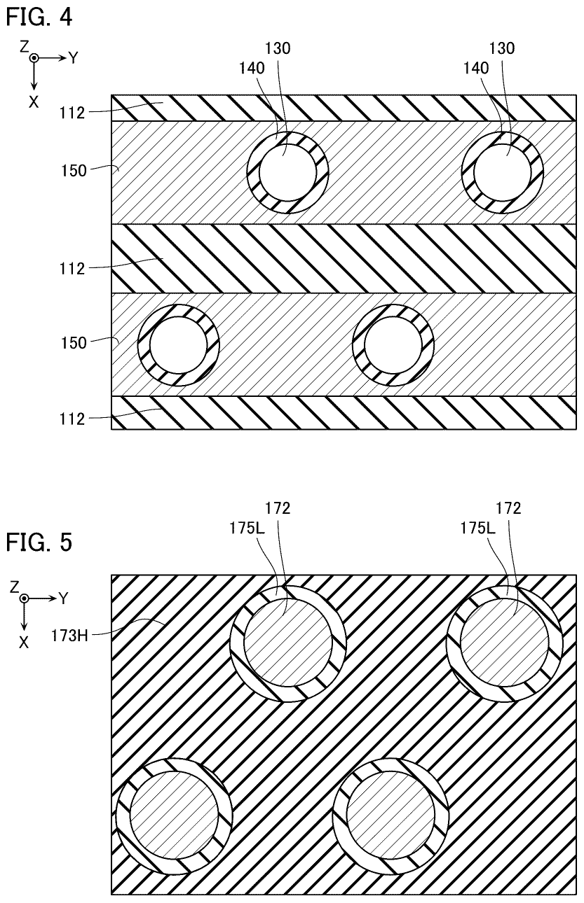

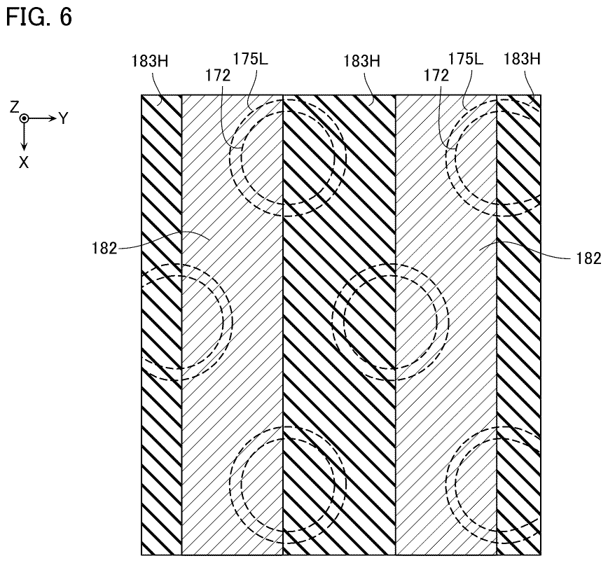

Next, with reference to FIG. 2 to FIG. 6, the structure of the memory region R_{MC} is described. FIG. 3 is a schematic cross-sectional view illustrating a part of the configuration of the memory region R_{MC}. FIG. 4 is a schematic cross-sectional view of the configuration illustrated in FIG. 3 taken along a line A-A′ viewed in an arrow direction. FIG. 5 is a schematic cross-sectional view of the configuration illustrated in FIG. 3 taken along a line B-B′ viewed in an arrow direction. FIG. 6 is a schematic cross-sectional view of the configuration illustrated in FIG. 3 taken along a line C-C′ viewed in an arrow direction. In FIG. 6, a part of the configuration illustrated in FIG. 5 is indicated by dotted lines.

The transistor layer L_{Tr} in the memory region R_{MC} includes, for example, as illustrated in FIG. 3, an insulating layer 111 disposed on an upper surface of the capacitor layer L_{CP} and an insulating layer 113 disposed above the insulating layer 111. The transistor layer L_{Tr} in the memory region R_{MC} includes, for example, as illustrated in FIG. 4, a plurality of insulating layers 112 and a plurality of conductive layers 150 which are disposed between the insulating layer 111 and the insulating layer 113 and alternately arranged in the X-direction. The transistor layer L_{Tr} in the memory region R_{MC} includes, for example, as illustrated in FIG. 4, a plurality of semiconductor layers 130 arranged in the X-direction and the Y-direction corresponding to the plurality of conductive layers 150 and insulating layers 140 disposed on outer peripheral surfaces of the semiconductor layers 130.

For example, as illustrated in FIG. 4, in the two conductive layers 150 adjacent in the X-direction, a plurality of the semiconductor layers 130 arranged corresponding to one conductive layer 150 and a plurality of the semiconductor layers 130 arranged corresponding to the other conductive layer 150 may be mutually different in position in the Y-direction.

The insulating layer 111, the insulating layer 112, and the insulating layer 113 contain, for example, silicon oxide (SiO₂).

The semiconductor layer 130 extends, for example, in the Z-direction, and has an approximately columnar shape. The semiconductor layer 130 is an oxide semiconductor, and functions as, for example, a channel region of the select transistor ST (FIG. 1). For example, the semiconductor layer 130 contains at least one element selected from a metal element group GP1, and contains oxygen (O). The metal element group GP1 includes indium (In), gallium (Ga), zinc (Zn), magnesium (Mg), aluminum (Al), manganese (Mn), tin (Sn), titanium (Ti), calcium (Ca), and cadmium (Cd). The semiconductor layer 130 may contain, for example, indium (In), gallium (Ga), zinc (Zn), and contain oxygen (O).

The insulating layer 140 extends, for example, in the Z-direction, and has an approximately cylindrical shape. The insulating layer 140 functions as, for example, a gate insulating film of the select transistor ST (FIG. 1). The insulating layer 140 contains, for example, silicon oxide (SiO₂). The insulating layer 140 may be a stacked structure of silicon oxide (SiO₂) and an insulating layer of silicon nitride (SiN) or another high dielectric constant material.

The conductive layer 150 functions as, for example, gate electrodes of a plurality of the select transistors ST arranged in the Y-direction and a word line WL (FIG. 1) of the memory cell array MCA. The conductive layer 150 may contain, for example, tungsten (W) or a stacked structure of titanium nitride (TiN) and tungsten (W).

For example, as illustrated in FIG. 3, the wiring layer L_{ML} of the memory region R_{MC} includes a plug layer L_{PL} disposed on an upper surface of the transistor layer L_{Tr}, a bit line layer L_{BL} disposed on an upper surface of the plug layer L_{PL}, and a conductive layer 192 and an insulating layer 190H disposed on an upper surface of the bit line layer L_{BL}.

For example, as illustrated in FIG. 3 and FIG. 5, the plug layer L_{PL} includes a conductive layer 170, a conductive layer 171, and a conductive layer 172, which are disposed on the upper surface of the transistor layer L_{Tr} in the order, and an insulating layer 175L at positions corresponding to the semiconductor layers 130. The conductive layer 170, the conductive layer 171, and the conductive layer 172 are each electrically connected to the semiconductor layer 130. The insulating layer 175L is, for example, as illustrated in FIG. 3 and FIG. 5, disposed on an outer peripheral surface of the conductive layer 170, the conductive layer 171, and the conductive layers 172. Hereinafter, a structure including the conductive layer 170, the conductive layer 171, and the conductive layer 172 is referred to as a plug PG in some cases.

The structure including the plug PG and the insulating layer 175L has, for example, as illustrated in FIG. 3 and FIG. 5, an approximately columnar shape extending in the Z-direction, and a plurality of the structures are disposed to be arranged in the X-direction and the Y-direction. The plug PG functions as, for example, a source electrode of the select transistor ST. Between the plurality of structures including the plug PG and the insulating layer 175L, an insulating layer 173H is disposed.

The conductive layer 170 contains, for example, at least one element selected from a metal element group GP2, and contains oxygen (O). The metal element group GP2 includes indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo). The conductive layer 170 may be, for example, indium tin oxide (InSnO).

The conductive layer 171 contains, for example, titanium nitride (TiN).

The conductive layer 172 contains, for example, tungsten (W), aluminum (Al), and molybdenum (Mo).

The insulating layer 173H and the insulating layer 175L are described later.

For example, as illustrated in FIG. 3 and FIG. 6, the bit line layer L_{BL} includes a conductive layer 181, a conductive layer 182, and a conductive layer 184 disposed on at least a part of the upper surface of the plug layer L_{PL} in the order at positions corresponding to the conductive layers 172. The conductive layer 181, the conductive layer 182, and the conductive layer 184 are electrically connected to a plurality of the conductive layers 172 arranged in the X-direction corresponding to the conductive layer 181, the conductive layer 182, and the conductive layer 184 (FIG. 6).

For example, as illustrated in FIG. 3 and FIG. 6, the structure including the conductive layer 181, the conductive layer 182, and the conductive layer 184 extends in the X-direction, and a plurality of the structures are disposed to be arranged in the Y-direction. The conductive layer 181, the conductive layer 182, and the conductive layer 184 function as, for example, bit lines BL (FIG. 1) of the memory cell array MCA. Between these structures arranged in the Y-direction, an insulating layer 183H is disposed.

The conductive layer 181 and the conductive layer 184 contain, for example, titanium nitride (TiN).

The conductive layer 182 contains, for example, a metal element, such as tungsten (W), aluminum (Al), and molybdenum (Mo).

The insulating layer 183H is described later.

The insulating layer 190H is described later.

For example, as illustrated in FIG. 2 and FIG. 3, the conductive layer 192 extends in the Z-direction, and has an approximately columnar shape. The conductive layer 192 has a lower surface connected to the conductive layer 184. The conductive layer 192 may contain, for example, tungsten (W) or a stacked structure of titanium nitride (TiN) and tungsten (W).

For example, as illustrated in FIG. 2, the wiring layer L_{UL} includes a wiring 301 disposed on an upper surface of the wiring layer L_{ML}, a wiring 302 disposed on an upper surface of the wiring 301 to be connected to the wiring 301, and a wiring 303 disposed on an upper surface of the wiring 302 to be connected to the wiring 302. Between the wiring 301, the wiring 302, and the wiring 303, for example, an insulating layer 304 of silicon oxide (SiO₂) or the like is disposed.

The wiring 301, the wiring 302, and the wiring 303 function as, for example, wirings for applying a voltage and a current to the bit line BL. The wiring 301, the wiring 302, and the wiring 303 contain, for example, copper (Cu), tungsten (W), and aluminum (Al).

For example, as illustrated in FIG. 2 and FIG. 3, the capacitor layer L_{CP} in the memory region R_{MC} includes a plurality of conductive layers 120 disposed corresponding to the plurality of semiconductor layers 130 and connected to respective lower ends of the plurality of semiconductor layers 130, a plurality of conductive layers 201 disposed corresponding to these plurality of conductive layers 120 and connected to respective lower ends of the plurality of conductive layers 120, and a plurality of conductive layers 121 disposed on outer peripheral surfaces of these plurality of conductive layers 120 and outer peripheral surfaces and lower surfaces of the plurality of conductive layers 201. The capacitor layer L_{CP} includes insulating layers 202 disposed on outer peripheral surfaces and lower surfaces of the conductive layers 121 and conductive layers 203 disposed on outer peripheral surfaces and lower surfaces of the insulating layers 202 (FIG. 3). In the following description, these configurations that achieve the capacitor Cap (FIG. 1) disposed in the capacitor layer L_{CP} of the memory region R_{MC} are referred to as a “capacitor structure CP10” in some cases. The capacitor structure CP10 includes, for example the conductive layer 120, the conductive layer 121, the conductive layer 201, the insulating layer 202, and the conductive layer 203. Between a plurality of the capacitor structures CP10, for example, an insulating layer 100 of silicon oxide (SiO₂) or the like is disposed.

The conductive layer 120 functions as, for example, a drain electrode of the select transistor ST (FIG. 1) and a part of one electrode of the capacitor Cap (FIG. 1). The conductive layer 120 may have an approximately circular shape in the XY cross-sectional surface, and may have a plug shape. The conductive layer 120 contains, for example, a material similar to that of the conductive layer 170. The conductive layer 120 may be, for example, indium tin oxide (InSnO).

The conductive layer 121 functions as, for example, a part of the one electrode of the capacitor Cap (FIG. 1). The conductive layer 121 may be, for example, titanium nitride (TiN).

The conductive layer 201 functions as a part of the one electrode of the capacitor Cap (FIG. 1). The conductive layer 201 includes, for example, a stacked structure of titanium nitride (TiN) and tungsten (W).

The insulating layer 202 functions as an insulating layer between the electrodes of the capacitor Cap (FIG. 1). The insulating layer 202 contains, for example, aluminum oxide (AlO). The insulating layer 202 may be, for example, silicon oxide (SiO₂) or another insulating metal oxide.

The conductive layer 203 functions as, for example, the other electrode of the capacitor Cap (FIG. 1). The conductive layer 203 includes, for example, a stacked structure of titanium nitride (TiN) and tungsten (W).

For example, as illustrated in FIG. 2, the plate line layer L_{PT} in the memory region R_{MC} includes a conductive layer 204 disposed at a lower surface of the capacitor layer L_{CP}. The conductive layer 204 is electrically connected to a plurality of the conductive layers 203. The conductive layer 204 functions as, for example, a plate line PL (FIG. 1). The conductive layer 204 may contain, for example, tungsten (W) or a stacked structure of titanium nitride (TiN) and tungsten (W).

### Structure of Peripheral Region R_{PC}

For example, as illustrated in FIG. 2, the transistor layer L_{Tr} in the peripheral region R_{PC} includes a part of the conductive layer 150 that functions as a word line WL and an electrode 151 connected to a lower end of the conductive layer 150. The electrode 151 may contain, for example, tungsten (W) or a stacked structure of titanium nitride (TiN) and tungsten (W).

For example, as illustrated in FIG. 2, the capacitor layer L_{CP} in the peripheral region R_{PC} includes a plurality of electrodes CC extending in the Z-direction. For example, the electrode CC has an upper end electrically connected to the electrode 151 and a lower end electrically connected to a part of a plurality of conductive layers 205 (described later) in the plate line layer L_{PT}. The electrode CC may contain, for example, tungsten (W) or a stacked structure of titanium nitride (TiN) and tungsten (W).

For example, as illustrated in FIG. 2, the plate line layer L_{PT} in the peripheral region R_{PC} includes a plurality of conductive layers 205. The conductive layer 205 may contain, for example, a material similar to that of the conductive layer 204.

For example, as illustrated in FIG. 2, the peripheral circuit layer L_{PC} of the peripheral region R_{PC} includes a plurality of transistors TrP1 disposed on the substrate Sub and a plurality of electrodes 210 connected to the plurality of transistors TrP1. The plurality of electrodes 210 have upper ends connected to the conductive layers 205. The respective plurality of electrodes 210 are connected to source regions, drain regions, gate electrodes, and the like of the plurality of transistors TrP1. The plurality of transistors TrP1 constitute, for example, the peripheral circuit PC (FIG. 1).

### Insulating Layers 173H, 183H, 190H, 175L

The insulating layer 173H, the insulating layer 183H, and the insulating layer 190H (FIG. 3) are hereinafter referred to as insulating layers belonging to an insulating layer group H, or simply the insulating layer group H in some cases. In a part farther from the capacitor layer L_{CP} than the transistor layer L_{Tr}, for example, as illustrated in FIG. 3, the insulating layers belonging to the insulating layer group H are formed.

The insulating layer group H contains, for example, a material having a relatively high density. For example, the insulating layer group H includes a high crystallinity film, and is less likely to cause diffusion of oxygen (O) through a crystal grain boundary and a highly amorphous part.

The insulating layer group H contains, for example, silicon (Si) and oxygen (O). The insulating layer group H contains, for example, silicon oxide (SiO₂) having a relatively high density.

The insulating layer group H is formed by, for example, Chemical Vapor Deposition (CVD). When the insulating layer group H is formed by CVD, the formation is performed at a relatively high temperature, for example, a stage temperature of about 400° C.

The insulating layer group H is formed by, for example, Atomic Layer Deposition (ALD). When the insulating layer group H is formed by ALD, for example, an oxidation condition in an oxidation step after supplying a raw material element is set to a condition conducive to crystallization, densification, and the like, such as a relatively high oxygen partial pressure and a relatively long processing time.

The insulating layer 175L is hereinafter referred to as an insulating layer belonging to an insulating layer group L, or simply the insulating layer group L in some cases.

The insulating layer group L contains, for example, a material having a relatively low density. For example, the insulating layer group L includes a low crystallinity film, and easily causes diffusion of oxygen (O) through a crystal grain boundary and a highly amorphous part.

The insulating layer group L contains, for example, silicon (Si) and oxygen (O). The insulating layer group L contains, for example, silicon oxide (SiO₂) having a relatively low density.

The insulating layer group L is formed by, for example, CVD. When the insulating layer group L is formed by CVD, the formation is performed at a relatively low temperature, for example, a stage temperature of about 300° C.

The insulating layer group L is formed by, for example, ALD. When the insulating layer group L is formed by ALD, for example, an oxidation condition in an oxidation step after supplying a raw material element is set to a condition where crystallization, densification, and the like are less likely to proceed, such as a relatively low oxygen partial pressure and a relatively short processing time.

The density of the insulating layer group H is higher than the density of the insulating layer group L. Here, the density is a film density. For example, an average density of a plurality of materials constituting the insulating layer group H is higher than an average density of a plurality of materials constituting the insulating layer group L. The densities of the materials contained in the insulating layer group H and the insulating layer group L can be measured by, for example, Electron Energy Loss Spectroscopy or X-Ray Reflectivity.

### Metal Element Concentration of Insulating Layers 173H, 175L

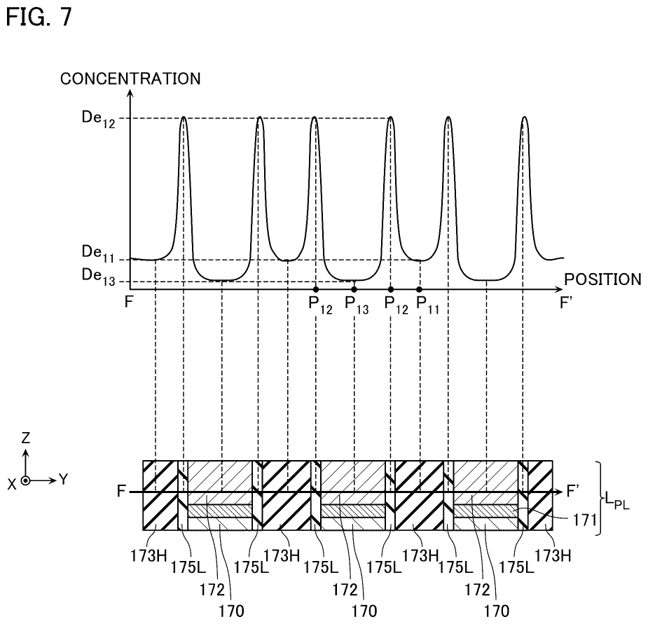

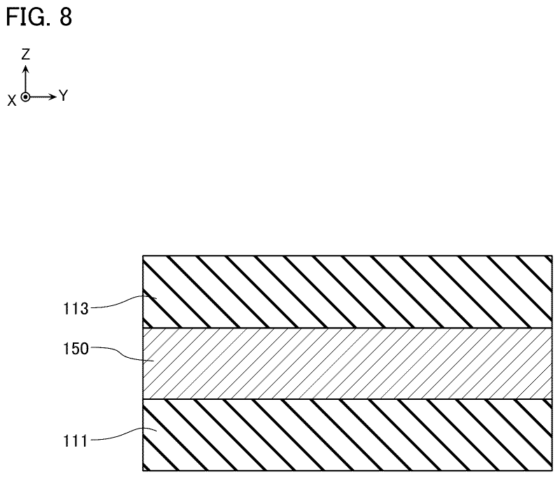

FIG. 7 is a drawing for describing a metal element concentration distribution of a part of the configuration of the semiconductor device according to the embodiment. The lower part of FIG. 7 is a drawing corresponding to the plug layer L_{PL}. The upper part of FIG. 7 is a graph indicating the metal element concentration of the portions along a line F-F′ illustrated in the lower part of FIG. 7.

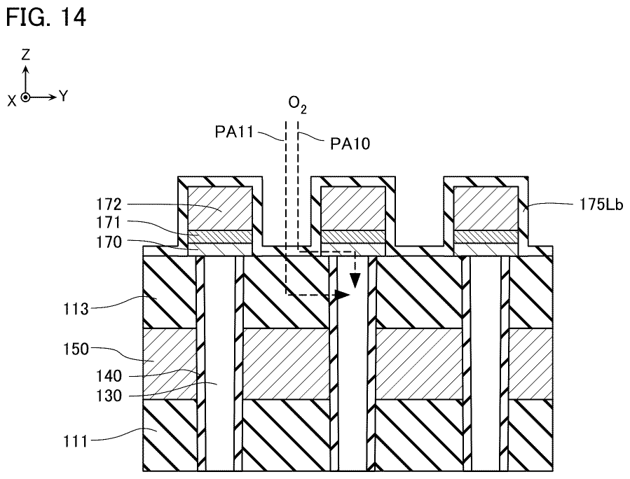

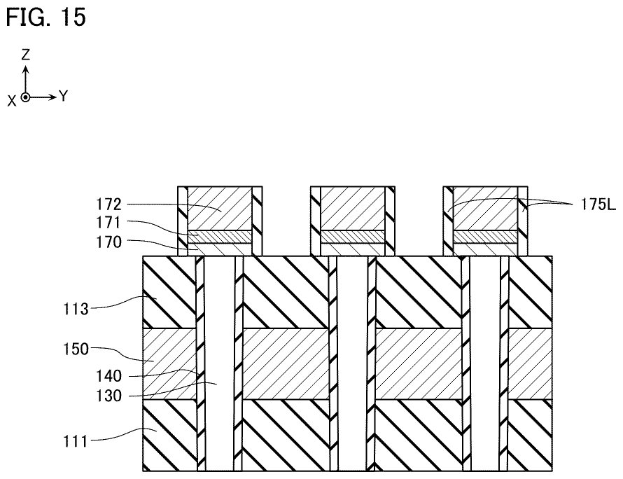

The insulating layer 175L and the insulating layer 173H contain, for example, at least one element selected from the metal element group GP1 or the metal element group GP2, and contain oxygen (O). The insulating layer 175L and the insulating layer 173H may be an insulating layer, for example, in which at least one element selected from the metal element group GP1 or the metal element group GP2 is diffused in an insulating film of silicon oxide (SiO₂) or the like. The metal element group GP1 is diffused from the semiconductor layer 130 to the insulating layer 175L, 173H, and the metal element group GP2 is diffused from the conductive layer 170 to the insulating layer 175L, 173H in an oxygen supply process (FIG. 14) described later.

In the following description, for example, a total concentration of one or a plurality of elements selected from the metal element group GP1 or the metal element group GP2 in the insulating layer 175L, the insulating layer 173H, and the conductive layer 172 is referred to as a metal element concentration in some cases.

In the graph of the upper part of FIG. 7, the metal element concentration at a position P₁₁ inside the insulating layer 173H is indicated as a concentration De₁₁, the metal element concentration at a position P₁₂ inside the insulating layer 175L is indicated as a concentration De₁₂, and the metal element concentration at a position P₁₃ inside the conductive layer 172 is indicated as a concentration De₁₃.

The concentration De₁₂ inside the insulating layer 175L is higher than the concentration De₁₁ inside the insulating layer 173H. The insulating layer 175L includes, for example, a film having a relatively low density, and the insulating layer 173H includes, for example, a film having a relatively high density. Metal elements are more easily diffused in the low-density film than in the high-density film. Therefore, in the oxygen supply process (FIG. 14) described later, a relatively large amount of the metal element is diffused from the semiconductor layer 130 and the conductive layer 170 in the insulating layer 175L, and a relatively small amount of the metal element is diffused in the insulating layer 173H.

The concentration De₁₃ inside the conductive layer 172 is lower than the concentration De₁₁ inside the insulating layer 173H. The conductive layer 170 contains a material, such as tungsten (W), in which another metal element is less likely to be diffused. Therefore, in the oxygen supply process described later, an extremely small amount of the metal element is diffused in the conductive layer 172.

The metal element concentration can be measured by, for example, Energy Dispersive X-ray Spectroscopy or Electron Energy Loss Spectroscopy.

### Manufacturing Method

Next, with reference to FIG. 8 to FIG. 18, a method of manufacturing the semiconductor device according to the embodiment is described. FIG. 8 to FIG. 18 are schematic cross-sectional views for describing the method of manufacturing the semiconductor device according to the first embodiment. Hereinafter, the drawings according to the manufacturing method are schematically illustrated, and for convenience of description, a part of a configuration and the like is omitted in some cases.

In the manufacturing method, the peripheral circuit layer L_{PC} (FIG. 2), the plate line layer L_{PT} (FIG. 2), and the capacitor layer L_{CP} (FIG. 2) are formed above the substrate Sub (not illustrated in FIG. 8). For example, as illustrated in FIG. 8, on the upper surface of the capacitor layer L_{CP}, the insulating layer 111, the insulating layer 112 (FIG. 4) and the conductive layer 150, and the insulating layer 113 are formed in the order. This process is performed by, for example, CVD and Reactive Ion Etching (RIE).

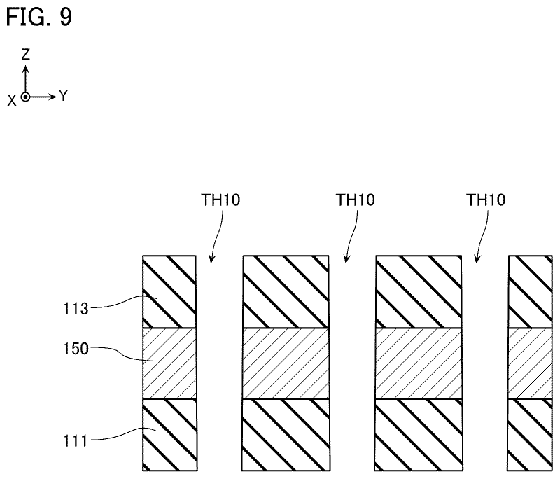

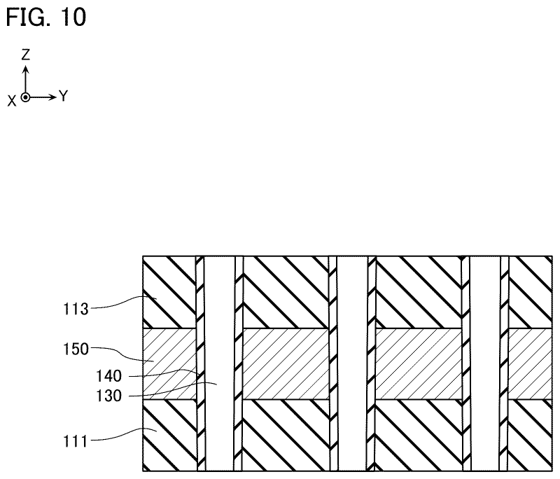

Next, for example, as illustrated in FIG. 9, openings TH10 are formed. The opening TH10 extends in the Z-direction, penetrates the insulating layer 113, the conductive layer 150, and the insulating layer 111, and exposes the conductive layer 120 (FIG. 3). This process is performed by, for example, RIE.

Next, for example, as illustrated in FIG. 10, the insulating layer 140 and the semiconductor layer 130 are formed at the openings TH10. The insulating layer 140 is formed by forming an insulating layer containing the material similar to that of the insulating layer 140 on internal surfaces and bottom surfaces of the openings TH10 and then removing the insulating layer at the part formed on the bottom surfaces of the openings TH10. The semiconductor layer 130 is formed to be in contact with an internal surface of the insulating layer 140 and fill the openings TH10. This process is performed by, for example, ALD, CVD, RIE, and Chemical Mechanical Planarization (CMP).

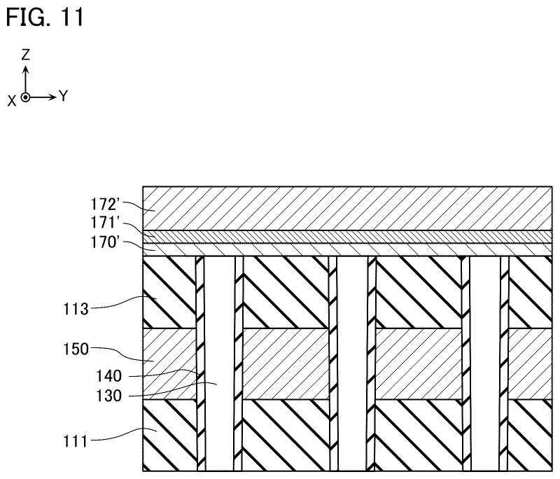

Next, for example, as illustrated in FIG. 11, a conductive layer 170′, a conductive layer 171′, and a conductive layer 172′ formed in the order on an upper surface of the structure illustrated in FIG. 10. The conductive layer 170′, the conductive layer 171′, and the conductive layer 172′ contain, for example, the material similar to that of the conductive layer 170, the conductive layer 171, and the conductive layer 172, respectively. This process is performed by, for example, CVD.

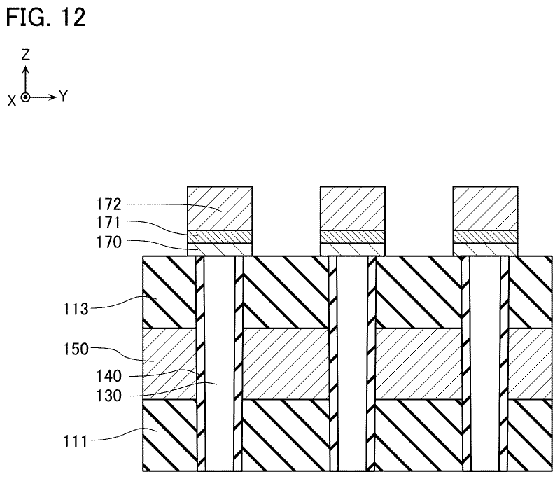

Next, for example, as illustrated in FIG. 12, a mask material is formed at positions corresponding to the conductive layer 170, the conductive layer 171, and the conductive layer 172 by photolithography or the like, and the part not covered with the mask material is removed, thereby forming the conductive layer 170, the conductive layer 171, and the conductive layer 172. This process is performed by, for example, RIE.

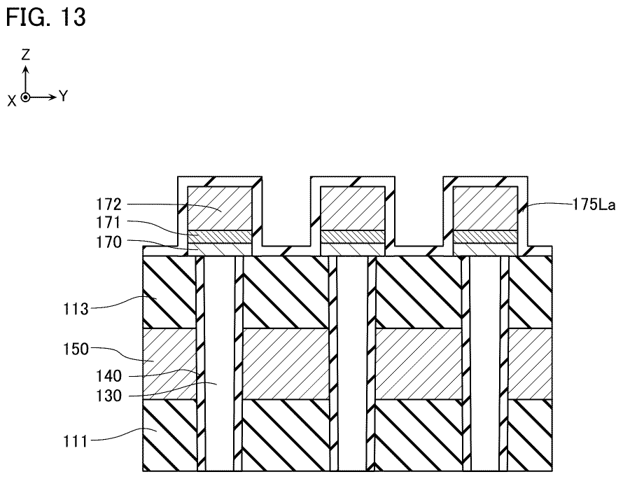

Next, for example, as illustrated in FIG. 13, an insulating layer 175La is formed on an upper surface of the insulating layer 113, side surfaces of the conductive layer 170, the conductive layer 171, and the conductive layer 172, and an upper surface of the conductive layer 172. The insulating layer 175La contains the material similar to that of the insulating layer 175L. While the insulating layer 175La may contain at least one element selected from the metal element group GP1 or the metal element group GP2, the metal element concentration of the insulating layer 175La is lower than the metal element concentration of the insulating layer 175L. This process is performed by CVD, ALD, or the like.

Next, for example, as illustrated in FIG. 14, oxygen is supplied to the semiconductor layer 130, for example, through oxygen supply paths PA10, PA11. By this process, the metal element included in the metal element group GP1 is diffused from the semiconductor layer 130 to the insulating layer 175La. The metal element included in the metal element group GP2 is diffused from the conductive layer 170 to the insulating layer 175La. This diffusion transforms the insulating layer 175La into an insulating layer 175Lb. The insulating layer 175Lb contains the material similar to that of the insulating layer 175L. The metal element concentration of the insulating layer 175Lb is similar to the metal element concentration of the insulating layer 175L. This process is performed by, for example, an annealing process at about 500° C. under an oxygen (O) atmosphere.

The oxygen supply path PA10 is, for example, a path through which oxygen (O) can be supplied from an upper surface of the semiconductor layer 130 via the insulating layer 175Lb, and the conductive layer 170 of indium tin oxide (InSnO) or the like.

The oxygen supply path PA11 is, for example, a path through which oxygen (O) can be supplied from a side surface of the semiconductor layer 130 via the insulating layer 175Lb, and the insulating layer 113 and the insulating layer 140 of silicon oxide (SiO₂) or the like.

Next, for example, as illustrated in FIG. 15, the part on the upper surface of the insulating layer 113 and the part on the upper surface of the conductive layer 172 of the insulating layer 175Lb are removed, thereby forming the insulating layer 175L. This process is performed by, for example, RIE.

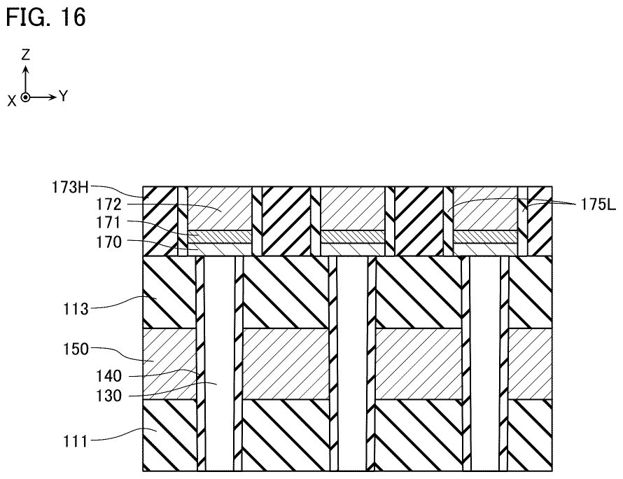

Next, for example, as illustrated in FIG. 16, an insulating layer containing the material similar to that of the insulating layer 173H is formed on an upper surface of the structure illustrated in FIG. 15, and its upper surface is removed until an upper surface part of the conductive layer 172 is exposed, thereby forming the insulating layer 173H. This process is performed by, for example, CVD, ALD, or CMP. In this process and following processes, the metal element included in the metal element group GP1 or the metal element group GP2 is diffused from the semiconductor layer 130, the conductive layer 170, and the insulating layer 175L to the insulating layer 173H.

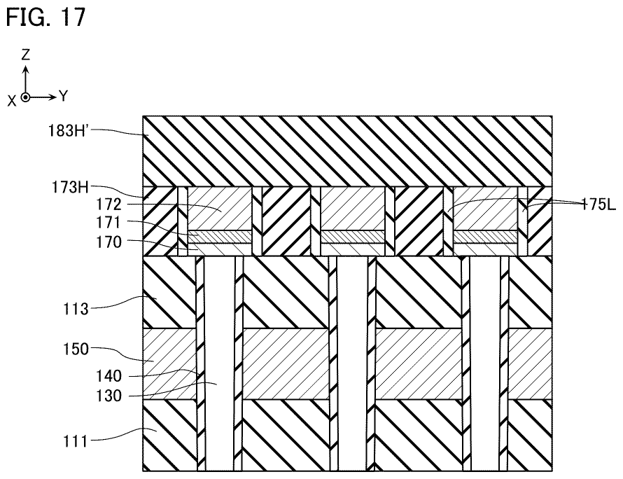

Next, for example, as illustrated in FIG. 17, an insulating layer 183H′ containing the material similar to that of the insulating layer 183H is formed on an upper surface of the structure illustrated in FIG. 16. This process is performed by, for example, CVD.

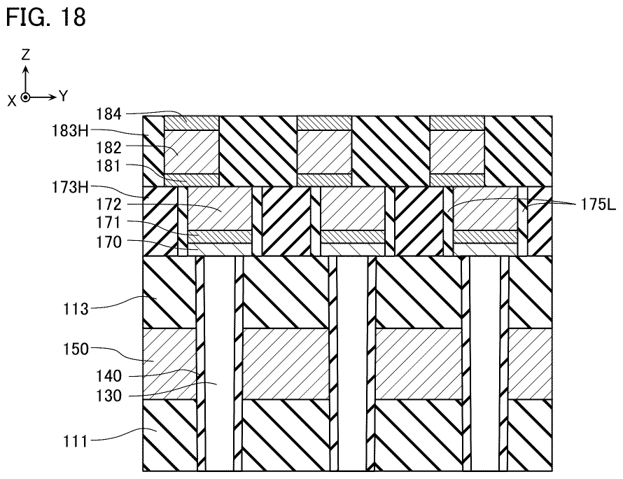

Next, for example, as illustrated in FIG. 18, the conductive layer 181, the conductive layer 182, the conductive layer 184, and the insulating layer 183H are formed. This process may be performed by, for example, a damascene method. In the damascene method of this process, openings are formed at portions of the insulating layer 183H′ at which the conductive layer 181, the conductive layer 182, and the conductive layer 184 are formed, and the conductive layer 181, the conductive layer 182, and the conductive layer 184 are formed inside the openings. This process is performed by, for example, CVD, RIE, and CMP.

Next, the wiring layer L_{UL} (FIG. 2) and the like are formed on an upper surface of the structure illustrated in FIG. 18, and thus the semiconductor device according to the first embodiment is manufactured.

### Comparative Example

In Comparative Example 1, the insulating layer 175L (FIG. 3) disposed on the outer peripheral surface of the plug PG (FIG. 3) is not provided, and for example, only an insulating layer having a high density, such as the insulating layer 173H, is provided between the adjacent plugs PG (FIG. 3). In the configuration such as Comparative Example 1, in the oxygen supply process (FIG. 14), since the insulating layer 175L having a low density that easily transmits oxygen is not provided, a sufficient amount of oxygen cannot be supplied to the semiconductor layer 130 in some cases. In this case, the satisfactory switching property of the select transistor ST (FIG. 1) is not provided in some cases.

In Comparative Example 2, the insulating layer 173H (FIG. 3) disposed between the adjacent plugs PG (FIG. 3) is not provided, and for example, only an insulating layer having a low density, such as the insulating layer 175L, is provided between the adjacent plugs PG. In the configuration such as Comparative Example 2, for example, in the oxygen supply process (FIG. 14), a large amount of the metal element is diffused in the insulating layer having a low density, and the adjacent plugs PG are conducted to one another in some cases.

### Effects

In the semiconductor device according to the embodiment, in the oxygen supply process (FIG. 14), a sufficient amount of oxygen can be supplied to the semiconductor layer 130 via the insulating layer 175Lb that easily transmits oxygen. Accordingly, the satisfactory switching property of the select transistor ST (FIG. 1) can be provided.

Further, in the semiconductor device according to the embodiment, since the insulating layer 173H containing a high-density material in which the metal element is less likely to be diffused is disposed between the adjacent plugs PG (FIG. 3), the adjacent plugs PG can be properly insulated from one another.

### Modification of First Embodiment

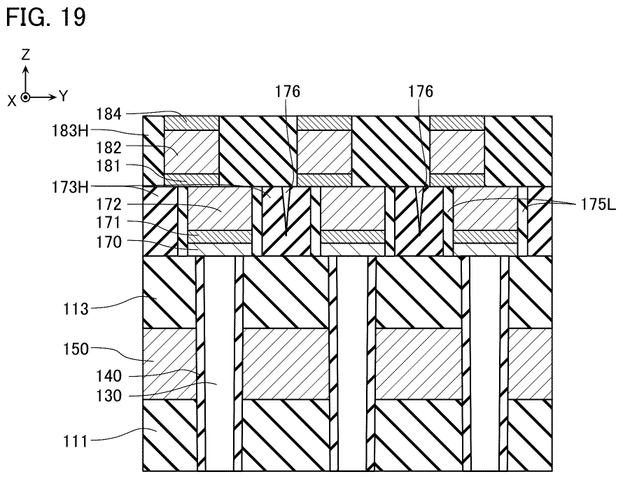

Next, with reference to FIG. 19, a modification of the semiconductor device according to the first embodiment is described. FIG. 19 is a schematic cross-sectional view illustrating a part of a configuration of a semiconductor device according to the modification.

The semiconductor device according to the modification is basically configured similarly to the semiconductor device (FIG. 3) according to the first embodiment. However, the semiconductor device (FIG. 19) according to the modification is provided with cavities 176 inside the insulating layer 173H.

The cavity 176 means what is called a space surrounded by a solid material disposed around a part at which the cavity 176 is provided, and the part at which the cavity 176 is provided does not contain any solid material. The cavity 176 is, for example, a space including air that contains a mixture of a plurality of gasses, such as nitrogen, oxygen, and a noble gas. The cavity 176 may be degassed so as not to contain any gas.

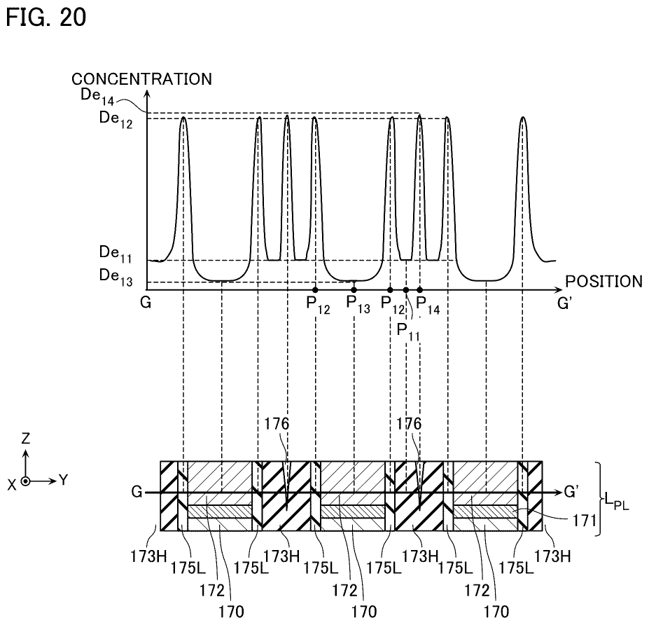

FIG. 20 is a drawing for describing a metal element concentration distribution of this modification. The lower part of FIG. 20 is a drawing corresponding to the plug layer L_{PL}. The upper part of FIG. 20 is a graph indicating the metal element concentration of the portions along a line G-G′ illustrated in the lower part of FIG. 20.

In the graph of the upper part of FIG. 20, in the insulating layer 173H, the metal element concentration at a position P₁₁ between the insulating layer 175L and the cavity 176 is indicated as a concentration De₁₁, and the metal element concentration at a position P₁₄ at an end portion of the insulating layer 173H in contact with the cavity 176 is indicated as a concentration De₁₄.

The concentration De₁₄ is higher than the concentration De₁₁. The metal element is easily diffused and segregated to the end portion of the insulating layer 173H in contact with the cavity 176. Therefore, in the oxygen supply process (FIG. 14), a relatively large amount of the metal element is diffused to the end portion of the insulating layer 173H in contact with the cavity 176.

While the concentration De₁₄ is higher than the concentration De₁₂ in the example illustrated in FIG. 20, the concentration De₁₄ may be similar to the concentration De₁₂, and the concentration De₁₄ may be lower than the concentration De₁₂.

### Second Embodiment

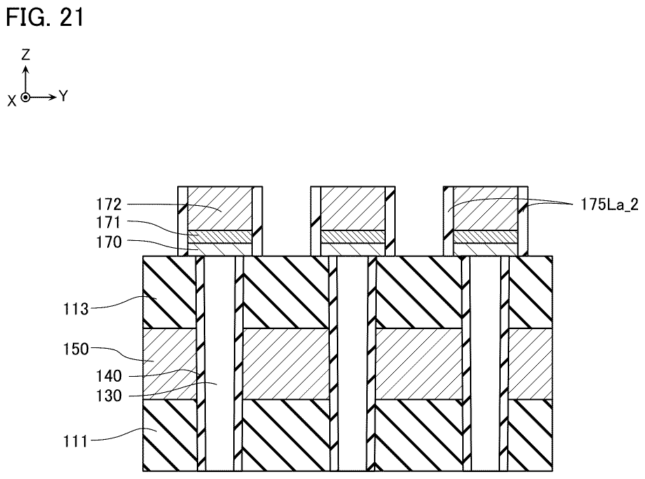

Next, with reference to FIG. 21 to FIG. 25, a semiconductor device according to the second embodiment is described.

The semiconductor device according to the embodiment is basically configured similarly to the semiconductor device (FIG. 3) according to the first embodiment. However, the semiconductor device according to the embodiment is manufactured by a manufacturing method partially different from that of the first embodiment.

### Manufacturing Method

FIG. 21 to FIG. 25 are schematic cross-sectional views for describing the method of manufacturing the semiconductor device according to the embodiment.

The semiconductor device according to the embodiment is basically manufactured similarly to the semiconductor device according to the first embodiment. However, in the manufacturing method of the semiconductor device according to the embodiment, processes illustrated in FIG. 21 to FIG. 25 are performed following the processes described with reference to FIG. 8 to FIG. 13.

For example, in the process illustrated in FIG. 21, the part on the upper surface of the insulating layer 113 and the part on the upper surface of the conductive layer 172 of the insulating layer 175La are removed, thereby forming an insulating layer 175La_2. This process is performed by, for example, RIE.

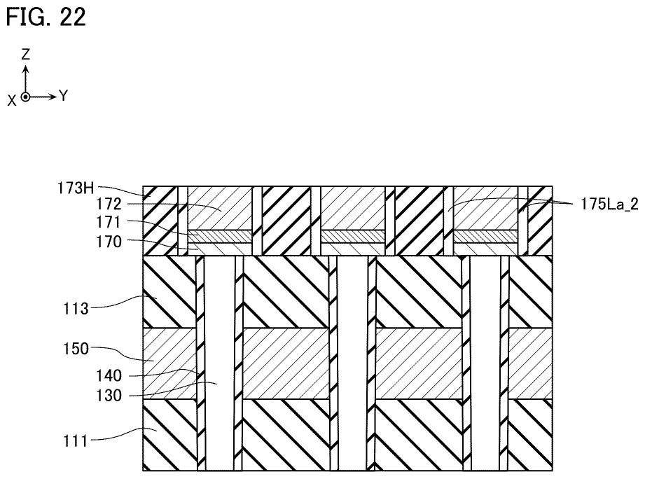

Next, for example, as illustrated in FIG. 22, an insulating layer containing the material similar to that of the insulating layer 173H is formed on an upper surface of the structure illustrated in FIG. 21, and its upper surface is removed until an upper surface part of the conductive layer 172 is exposed, thereby forming the insulating layer 173H. This process is performed by, for example, CVD, ALD, or CMP.

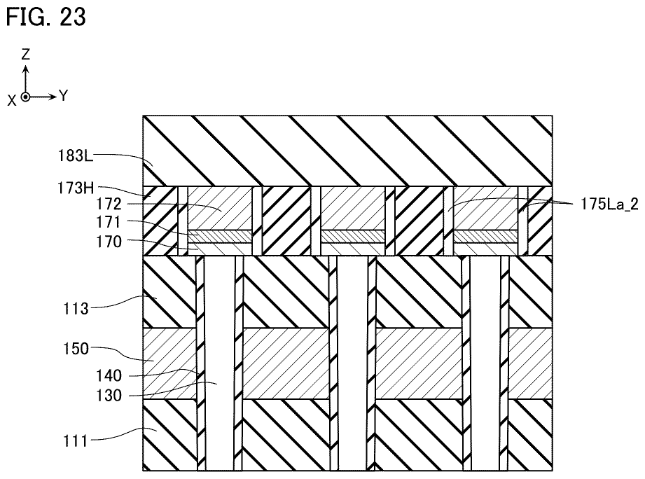

Next, for example, as illustrated in FIG. 23, an insulating layer 183L is formed on an upper surface of the structure illustrated in FIG. 22. The insulating layer 183L is, for example, an insulating layer belonging to the insulating layer group L. This process is performed by, for example, CVD or ALD.

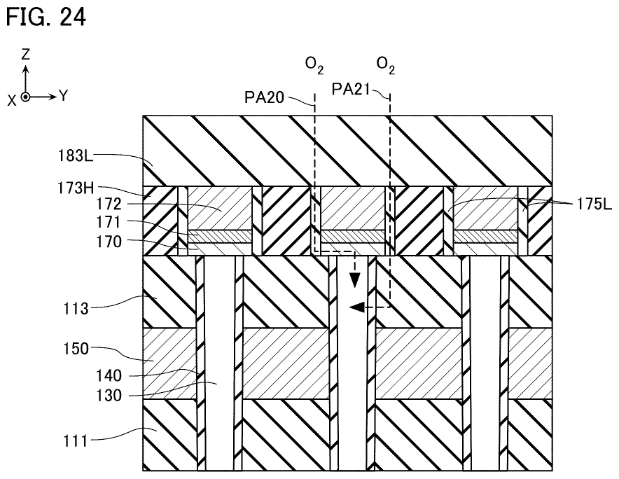

Next, for example, as illustrated in FIG. 24, oxygen is supplied to the semiconductor layer 130, for example, through oxygen supply paths PA20, PA21. By this process, the metal element included in the metal element group GP1 is diffused from the semiconductor layer 130 to the insulating layer 175La_2. The metal element included in the metal element group GP2 is diffused from the conductive layer 170 to the insulating layer 175La_2. This diffusion transforms the insulating layer 175La_2 into the insulating layer 175L. This process is performed by, for example, an annealing process at about 500° C. under an oxygen (O) atmosphere.

The oxygen supply path PA20 is, for example, a path through which oxygen (O) can be supplied from an upper surface of the semiconductor layer 130 via the insulating layer 183L, the insulating layer 175L, and the conductive layer 170 of indium tin oxide (InSnO) or the like.

The oxygen supply path PA21 is, for example, a path through which oxygen (O) can be supplied from a side surface of the semiconductor layer 130 via the insulating layer 183L, the insulating layer 175L, and the insulating layers 113, 140 of silicon oxide (SiO₂) or the like.

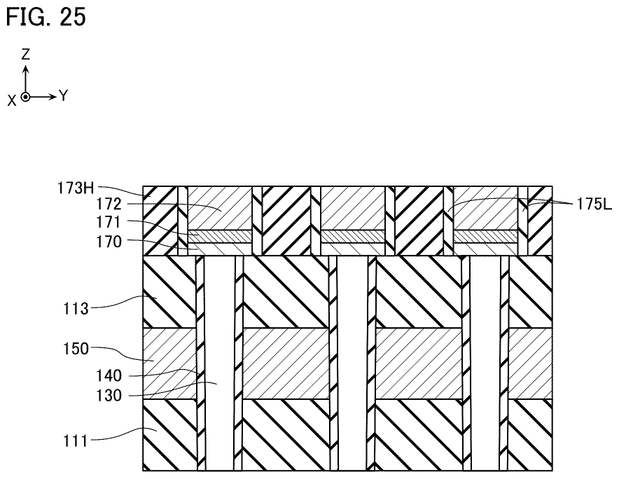

Next, for example, as illustrated in FIG. 25, the insulating layer 183L is removed. This process is performed by, for example, wet etching or RIE.

Next, for example, the processes similar to the processes described with reference to FIG. 17 and FIG. 18 are performed, and the wiring layer L_{UL} (FIG. 2) and the like are formed, thus the semiconductor device according to the second embodiment is manufactured.

### Effects

In the semiconductor device according to the embodiment, in the process (FIG. 24) of supplying oxygen to the semiconductor layer 130, oxidation of the conductive layer 172 can be avoided by passing through the insulating layer 183L.

### Third Embodiment

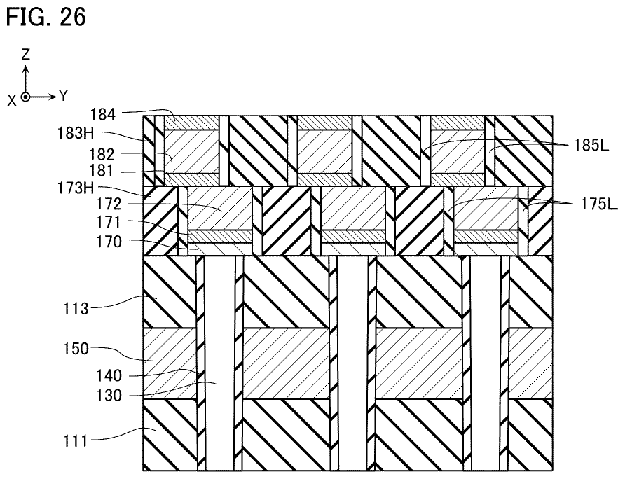

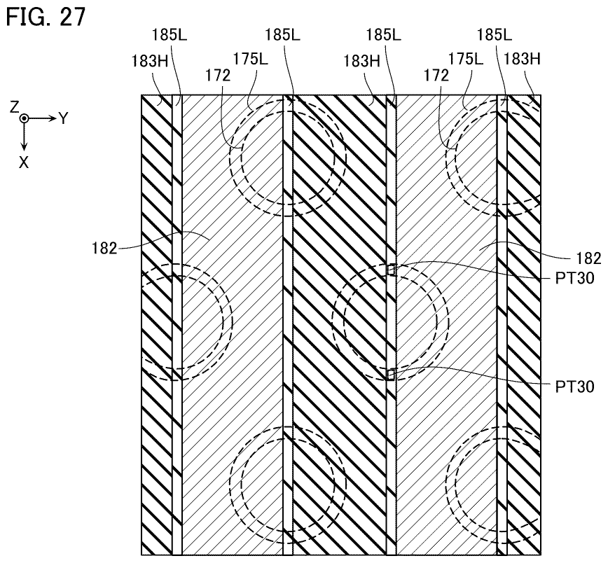

Next, with reference to FIG. 26 and FIG. 27, a semiconductor device according to the third embodiment is described.

The semiconductor device according to the embodiment is basically configured similarly to the semiconductor device (FIG. 3) according to the first embodiment. However, the semiconductor device (FIG. 26) according to the embodiment is different from the first embodiment, and includes an insulating layer 185L disposed each of both side surfaces in the Y-direction of the conductive layer 181, the conductive layer 182, and the conductive layer 184.

The insulating layer 185L is, for example, an insulating layer belonging to the insulating layer group L. For example, as illustrated in FIG. 27, the insulating layer 185L includes a portion PT30 that overlaps with the insulating layer 175L when viewed in the Z-direction and is in contact with the insulating layer 175L.

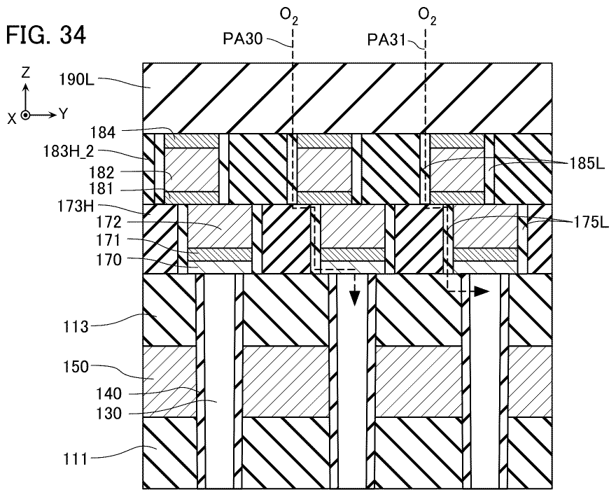

The insulating layer 185L and the insulating layer 183H contain, for example, at least one element selected from the metal element group GP1 or the metal element group GP2, and contain oxygen (O). The insulating layer 185L and the insulating layer 183H may be an insulating layer, for example, in which at least one element selected from the metal element group GP1 or the metal element group GP2 is diffused in an insulating film of silicon oxide (SiO₂) or the like. The metal element group GP1 is diffused from the semiconductor layer 130 to the insulating layer 185L, 183H, and the metal element group GP2 is diffused from the conductive layer 170 to the insulating layer 185L, 183H in an oxygen supply process (FIG. 34) described later and processes following the process of FIG. 34.

In the following description, for example, a total concentration of one or a plurality of elements selected from the metal element group GP1 or the metal element group GP2 in the insulating layer 185L, the insulating layer 183H, and the conductive layer 182 is referred to as a metal element concentration in some cases.

The metal element concentration inside the insulating layer 185L is higher than the metal element concentration inside the insulating layer 183H. The insulating layer 185L includes, for example, a film having a relatively low density, and the insulating layer 183H includes, for example, a film having a relatively high density. Therefore, in the oxygen supply process (FIG. 34) described later, a relatively large amount of the metal element is diffused from the semiconductor layer 130 and the conductive layer 170 in the insulating layer 185L, and a relatively small amount of the metal element is diffused in the insulating layer 183H.

The metal element concentration inside the conductive layer 182 is lower than the metal element concentration inside the insulating layer 183H. The conductive layer 182 contains a material, such as tungsten (W), in which another metal element is less likely to be diffused. Therefore, in the oxygen supply process (FIG. 34) described later, an extremely small amount of the metal element is diffused in the conductive layer 182.

### Manufacturing Method

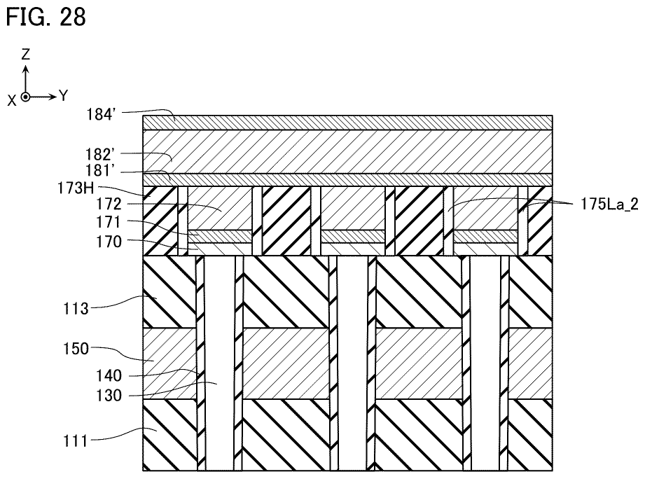

FIG. 28 to FIG. 35 are schematic cross-sectional views for describing the method of manufacturing the semiconductor device according to the embodiment.

The semiconductor device according to the embodiment is basically manufactured similarly to the semiconductor device according to the second embodiment. However, in the manufacturing method of the semiconductor device according to the embodiment, processes illustrated in FIG. 28 to FIG. 35 are performed following the process described with reference to FIG. 22.

For example, in the process illustrated in FIG. 28, a conductive layer 181′, a conductive layer 182′, and a conductive layer 184′ are formed in the order on an upper surface of the structure illustrated in FIG. 22. The conductive layer 181′, the conductive layer 182′, and the conductive layer 184′ contain, for example, the material similar to that of the conductive layer 181, the conductive layer 182, and the conductive layer 184, respectively. This process is performed by, for example, CVD.

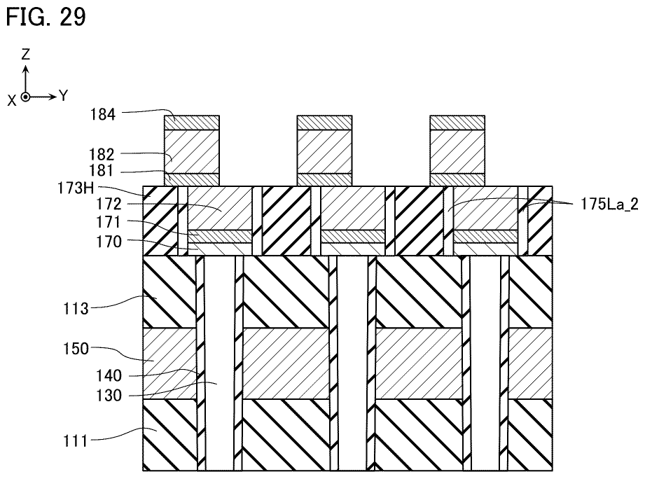

Next, for example, as illustrated in FIG. 29, a mask material is formed at positions corresponding to the conductive layer 181, the conductive layer 182, and the conductive layer 184 by photolithography or the like, and the part not covered with the mask material is removed, thereby forming the conductive layer 181, the conductive layer 182, and the conductive layer 184. This process is performed by, for example, RIE.

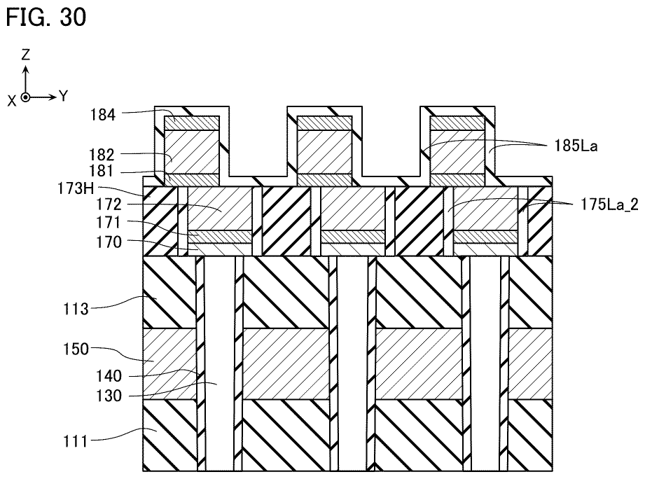

Next, for example, as illustrated in FIG. 30, an insulating layer 185La is formed on an upper surface of the insulating layer 173H, both side surfaces of the conductive layer 181, the conductive layer 182, and the conductive layer 184, and an upper surface of the conductive layer 184. The insulating layer 185La contains the material similar to that of the insulating layer 185L. While the insulating layer 185La may contain at least one element selected from the metal element group GP1 or the metal element group GP2, the metal element concentration of the insulating layer 185La is lower than the metal element concentration of the insulating layer 185L. This process is performed by, for example, CVD or ALD.

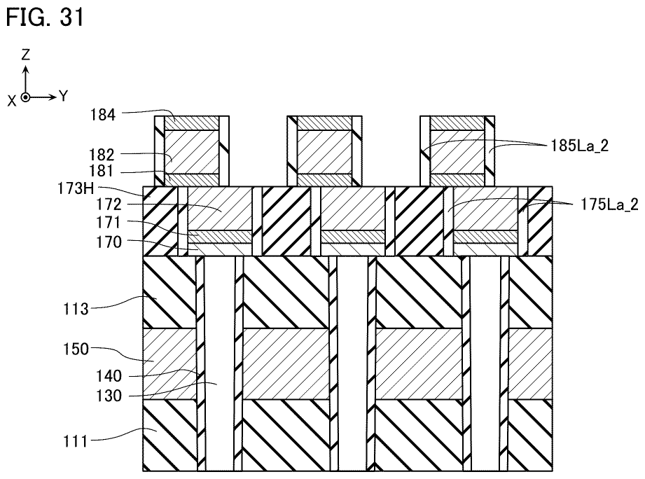

Next, for example, as illustrated in FIG. 31, the part on the upper surface of the insulating layer 173H and the part on the upper surface of the conductive layer 184 of the insulating layer 185La are removed, thereby forming an insulating layer 185La_2. This process is performed by, for example, RIE.

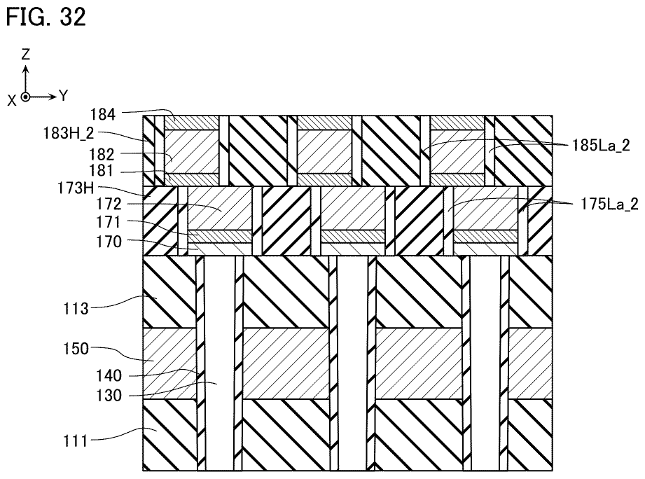

Next, for example, as illustrated in FIG. 32, an insulating layer containing the material similar to that of the insulating layer 183H is formed on an upper surface of the structure illustrated in FIG. 31, and its upper surface is removed until an upper surface part of the conductive layer 184 is exposed, thereby forming an insulating layer 183H_2. The insulating layer 183H_2 is, for example, an insulating layer belonging to the insulating layer group H. This process is performed by, for example, CVD, ALD, or CMP.

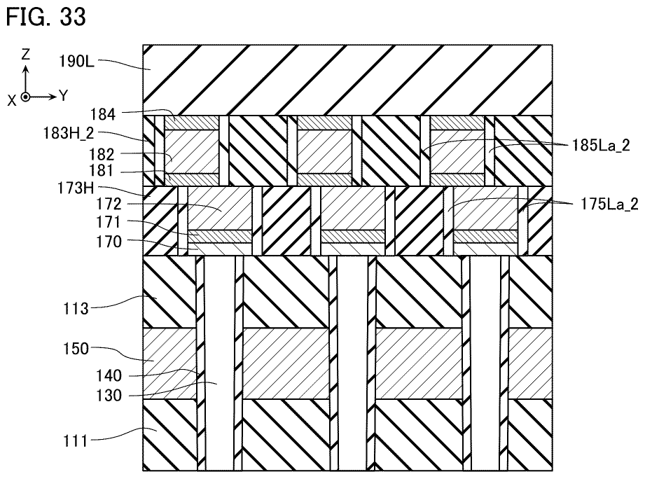

Next, for example, as illustrated in FIG. 33, an insulating layer 190L is formed on an upper surface of the structure illustrated in FIG. 32. The insulating layer 190L is, for example, an insulating layer belonging to the insulating layer group L. This process is performed by, for example, CVD or ALD.

Next, for example, as illustrated in FIG. 34, oxygen is supplied to the semiconductor layer 130, for example, through oxygen supply paths PA30, PA31. By this process, the metal element included in the metal element group GP1 is diffused from the semiconductor layer 130 to the insulating layer 175La_2 and the insulating layer 185La_2. The metal element included in the metal element group GP2 is diffused from the conductive layer 170 to the insulating layer 175La_2 and the insulating layer 185La_2. This diffusion transforms the insulating layer 175La_2 and the insulating layer 185La_2 into the insulating layer 175L and the insulating layer 185L. This process is performed by, for example, an annealing process at about 500° C. under an oxygen (O) atmosphere.

The oxygen supply path PA30 is, for example, a path through which oxygen (O) can be supplied from an upper surface of the semiconductor layer 130 via the insulating layer 190L, the insulating layer 185L, the insulating layer 175L, and the conductive layer 170 of indium tin oxide (InSnO) or the like. In the oxygen supply path PA30, the path between the insulating layer 185L and the insulating layer 175L may be formed via the portion PT30 (FIG. 27) in which the insulating layer 185L is directly in contact with the insulating layer 175L, or may be formed partially via the insulating layer 173H.

The oxygen supply path PA31 is, for example, a path through which oxygen (O) can be supplied from a side surface of the semiconductor layer 130 via the insulating layer 190L, the insulating layer 185L, the insulating layer 175L, and the insulating layers 113, 140 of silicon oxide (SiO₂) or the like. In the oxygen supply path PA31, the path between the insulating layer 185L and the insulating layer 175L may be formed via the portion PT30 (FIG. 27) in which the insulating layer 185L is directly in contact with the insulating layer 175L, or may be formed partially via the insulating layer 173H.

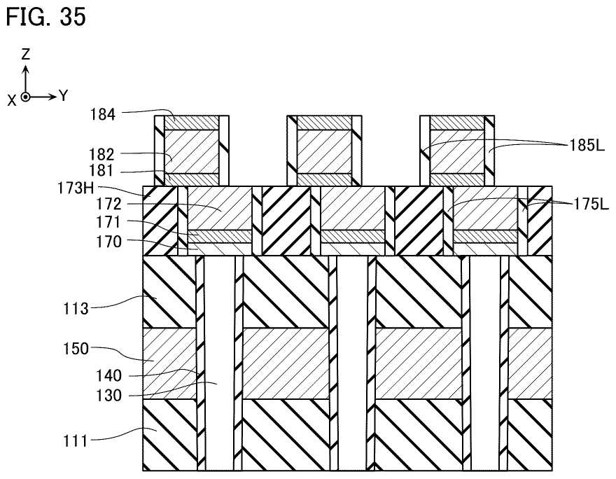

Next, for example, as illustrated in FIG. 35, the insulating layer 190L and the insulating layer 183H_2 are removed. This process is performed by, for example, wet etching or RIE.

Next, for example, an insulating layer containing the material similar to that of the insulating layer 183H is formed on an upper surface of the structure illustrated in FIG. 35, and thus the structure described with reference to FIG. 26 is formed.

### Effects

In the semiconductor device according to the embodiment, the process of supplying oxygen to the semiconductor layer 130 (FIG. 34) is performed in the later process compared with the first to the second embodiments. This allows recovery of oxygen loss due to oxygen removed from the semiconductor layer 130 in the manufacturing process, and allows supply of the sufficient amount of oxygen to the semiconductor layer 130. Accordingly, the satisfactory switching property of the select transistor ST (FIG. 1) can be provided.

### Fourth Embodiment

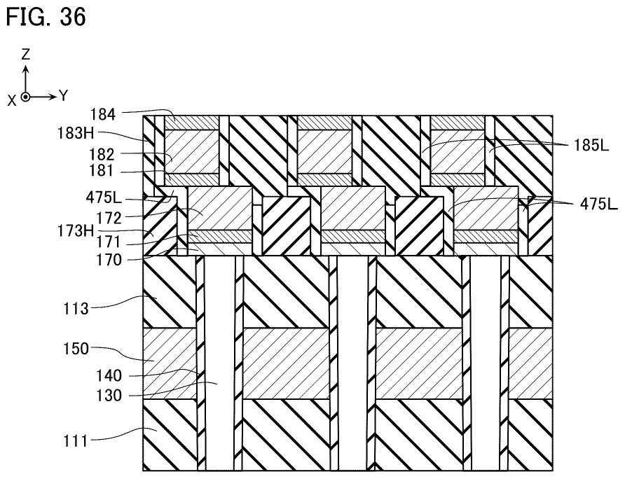

Next, with reference to FIG. 36, a semiconductor device according to the fourth embodiment is described.

The semiconductor device according to the embodiment is basically configured similarly to the semiconductor device (FIG. 26) according to the third embodiment. However, the semiconductor device (FIG. 36) according to the embodiment is different from the third embodiment, and includes an insulating layer 475L instead of the insulating layer 175L.

For example, as illustrated in FIG. 36, the insulating layer 475L is disposed in contact with the outer peripheral surface of the conductive layer 170 and the conductive layer 171, a part of the outer peripheral surface of the conductive layer 172, and a part of a lower surface of the conductive layer 181. A part of an upper surface of the insulating layer 475L is in contact with a lower surface of the insulating layer 185L.

The insulating layer 475L is, for example, an insulating layer belonging to the insulating layer group L.

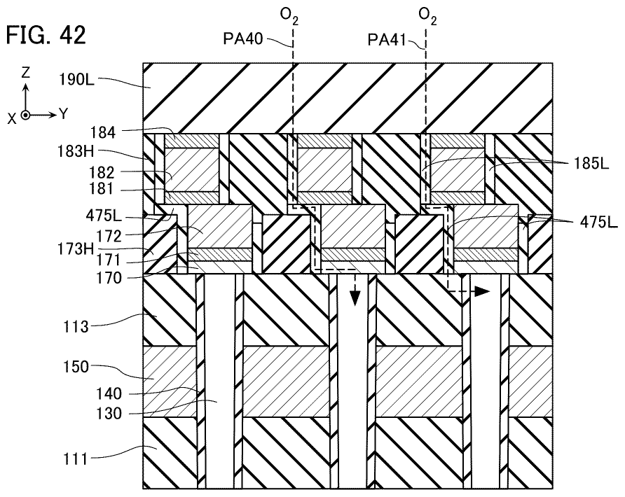

The insulating layer 475L contains, for example, at least one element selected from the metal element group GP1 or the metal element group GP2, and contains oxygen (O). The insulating layer 475L may be an insulating layer, for example, in which at least one element selected from the metal element group GP1 or the metal element group GP2 is diffused in an insulating film of silicon oxide (SiO₂) or the like. The metal element group GP1 is diffused from the semiconductor layer 130 to the insulating layer 475L, and the metal element group GP2 is diffused from the conductive layer 170 to the insulating layer 475L in an oxygen supply process (FIG. 42) described later and processes following the process of FIG. 42.

In the following description, for example, a total concentration of one or a plurality of elements selected from the metal element group GP1 or the metal element group GP2 in the insulating layer 475L is referred to as a metal element concentration in some cases.

The metal element concentration inside the insulating layer 475L is higher than the metal element concentration inside the insulating layer 173H. The insulating layer 475L includes, for example, a film having a relatively low density, and the insulating layer 173H includes, for example, a film having a relatively high density. Therefore, in the oxygen supply process (FIG. 42) described later, a relatively large amount of the metal element is diffused from the semiconductor layer 130 and the conductive layer 170 in the insulating layer 475L, and a relatively small amount of the metal element is diffused in the insulating layer 173H.

### Manufacturing Method

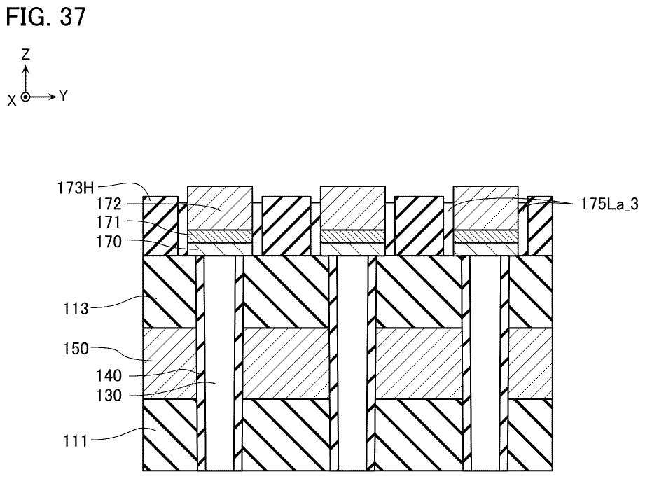

FIG. 37 to FIG. 42 are schematic cross-sectional views for describing the method of manufacturing the semiconductor device according to the embodiment.

The semiconductor device according to the embodiment is basically manufactured similarly to the semiconductor device according to the third embodiment. However, in the manufacturing method of the semiconductor device according to the embodiment, processes illustrated in FIG. 37 to FIG. 41 are performed instead of the processes described with reference to FIG. 28 to FIG. 31.

For example, in the process illustrated in FIG. 37, a part of the insulating layer 175La_2 (FIG. 22) is removed, thereby forming an insulating layer 175La_3. A part of the upper surface of the insulating layer 173H is removed. In this process, etching more easily progresses in the insulating layer 175La_2 containing the low-density material than in the insulating layer 173H. This process is performed by, for example, wet etching or RIE.

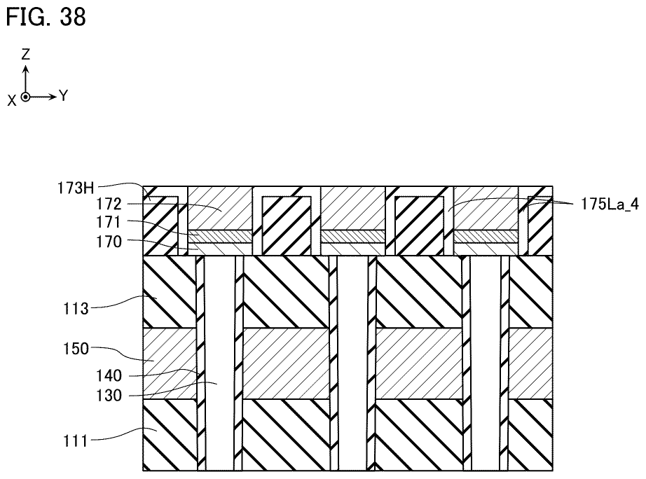

Next, for example, as illustrated in FIG. 38, an insulating layer containing the material similar to that of the insulating layer 175L is formed on an upper surface of the structure illustrated in FIG. 37, and its upper surface is removed until an upper surface part of the conductive layer 172 is exposed, thereby forming an insulating layer 175La_4. This process is performed by, for example, CVD, ALD, or CMP.

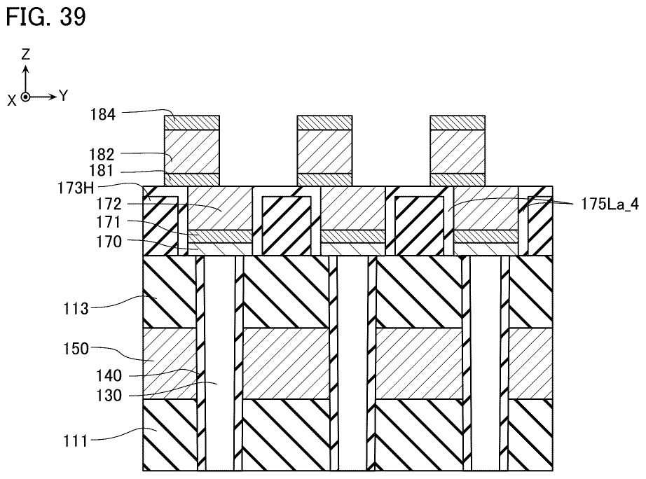

Next, for example, as illustrated in FIG. 39, the conductive layer 181, the conductive layer 182, and the conductive layer 184 are formed similarly to the processes described with reference to FIG. 28 and FIG. 29.

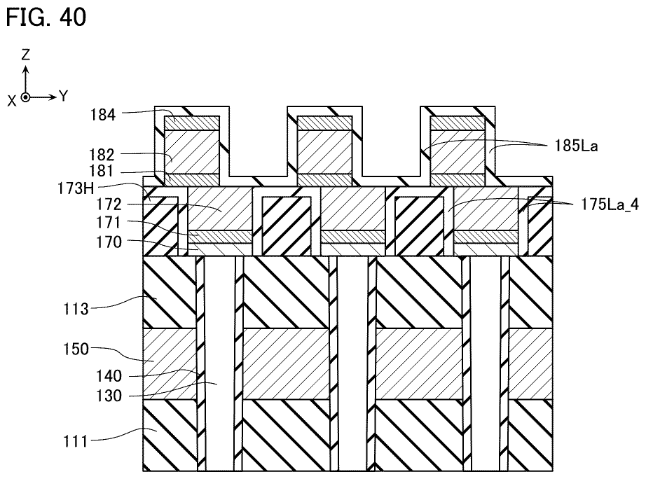

Next, for example, as illustrated in FIG. 40, the insulating layer 185La is formed on upper surfaces of the insulating layer 175La_4 and the conductive layer 172, both side surfaces of the conductive layer 181, the conductive layer 182, and the conductive layer 184, and the upper surface of the conductive layer 184. This process is performed by, for example, CVD or ALD.

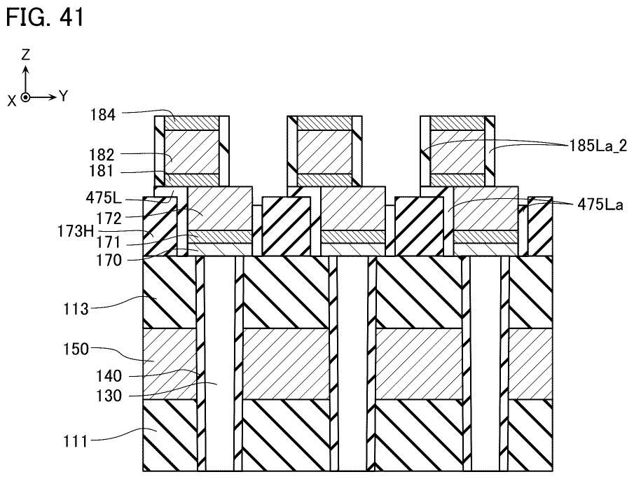

Next, for example, as illustrated in FIG. 41, the parts on the upper surfaces of the insulating layer 173H and the conductive layer 172 and the part on the upper surface of the conductive layer 184 of the insulating layer 185La and the insulating layer 175La_4 are removed, thereby forming an insulating layer 185La_2 and an insulating layer 475La. This process is performed by, for example, RIE.

Next, similarly to the process described with reference to FIG. 32, the insulating layer 183H_2 is formed.

Next, similarly to the process described with reference to FIG. 33, the insulating layer 190L is formed.

Next, for example, as illustrated in FIG. 42, oxygen is supplied to the semiconductor layer 130, for example, through oxygen supply paths PA40, PA41. By this process, the metal element included in the metal element group GP1 is diffused from the semiconductor layer 130 to the insulating layer 475La and the insulating layer 185La_2. The metal element included in the metal element group GP2 is diffused from the conductive layer 170 to the insulating layer 475La and the insulating layer 185La_2. This diffusion transforms the insulating layer 475La and the insulating layer 185La_2 into the insulating layer 475L and the insulating layer 185L. This process is performed by, for example, an annealing process at about 500° C. under an oxygen (O) atmosphere.

The oxygen supply path PA40 is, for example, a path through which oxygen (O) can be supplied from an upper surface of the semiconductor layer 130 via the insulating layer 190L, the insulating layer 185L, the insulating layer 475L, and the conductive layer 170 of indium tin oxide (InSnO) or the like.

The oxygen supply path PA41 is, for example, a path through which oxygen (O) can be supplied from a side surface of the semiconductor layer 130 via the insulating layer 190L, the insulating layer 185L, the insulating layer 475L, and the insulating layers 113, 140 of silicon oxide (SiO₂) or the like.

### Effects

In the semiconductor device according to the embodiment, since the oxygen supply paths PA40, PA41 are all configured of the insulating layers containing the low-density material in the oxygen supply process (FIG. 42), the sufficient amount of oxygen can be supplied to the semiconductor layer 130. Accordingly, the satisfactory switching property of the select transistor ST (FIG. 1) can be provided.

### other Embodiments

The semiconductor devices according to the first embodiment to the fourth embodiment have been described above. However, the semiconductor devices according to these embodiments are merely examples, and the specific configuration, operation, and the like are adjustable as appropriate.

For example, in the above description, the example in which the capacitor Cap (FIG. 1) is connected to the select transistor ST (FIG. 1) is described. In this example, the shape, the structure, and the like of the capacitor Cap can be adjusted as appropriate.

Additionally, in the above description, the example in which the capacitor Cap (FIG. 1) is employed as the memory portion connected to the select transistor ST (FIG. 1) is described. However, the memory portion need not be the capacitor Cap. For example, the memory portion may contain a ferroelectric material, a ferromagnet material, a chalcogen material such as GeSbTe, or another material and may store data using the characteristics of these materials. For example, in any of the structures described above, any of these materials may be contained in the insulating layer between the electrodes forming the capacitor Cap.

In the example above-described, the semiconductor layer 130 functions as the channel region of the select transistor ST (FIG. 1), and the semiconductor layer 130 extends in, for example, the Z-direction and has an approximately columnar shape. However, the semiconductor layer 130 may have an approximately cylindrical shape extending in the Z-direction. Further, an approximately columnar insulating layer, which contains silicon oxide (SiO₂), extending in the Z-direction may be disposed inside the semiconductor layer 130.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
an oxide semiconductor layer that is spaced from the substrate in a first direction intersecting with a surface of the substrate and contains a first metal element and oxygen (O);
a first wiring opposed to a part of the oxide semiconductor layer;
a gate insulating film disposed between the oxide semiconductor layer and the first wiring;
a first conductive layer that is in contact with one end in the first direction of the oxide semiconductor layer and contains a second metal element and oxygen (O);
a second wiring electrically connected to the first conductive layer; and
a first insulating portion in contact with the second wiring, wherein
the first insulating portion includes:
a first region; and
a second region between the first region and the second wiring, and
a concentration of the first metal element in the second region is higher than a concentration of the first metal element in the first region, or a concentration of the second metal element in the second region is higher than a concentration of the second metal element in the first region.

2. The semiconductor device according to claim 1, wherein
a density of the second region is lower than a density of the first region.

3. The semiconductor device according to claim 1, wherein
the first insulating portion includes a first insulating layer including the first region and a second insulating layer including the second region,
the second insulating layer is disposed between the first insulating layer and the second wiring, and
a density of the second insulating layer is lower than a density of the first insulating layer.

4. The semiconductor device according to claim 3, wherein
the first insulating layer and the second insulating layer contain silicon (Si) and oxygen (O).

5. The semiconductor device according to claim 1, wherein
the first metal element is one element selected from a group consisting of indium (In), gallium (Ga), zinc (Zn), magnesium (Mg), aluminum (Al), manganese (Mn), tin (Sn), titanium (Ti), calcium (Ca), and cadmium (Cd).

6. The semiconductor device according to claim 1, wherein
the second metal element is one element selected from a group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo).

7. The semiconductor device according to claim 1, further comprising:
a third wiring that is electrically connected to one end in the first direction of the second wiring and extends in a second direction intersecting with the first direction; and
a second insulating portion in contact with the third wiring, wherein
the second insulating portion includes:
a third region; and
a fourth region between the third region and the third wiring, and
a concentration of the first metal element in the fourth region is higher than a concentration of the first metal element in the third region, or a concentration of the second metal element in the fourth region is higher than a concentration of the second metal element in the third region.

8. The semiconductor device according to claim 7, wherein
a density of the fourth region is lower than a density of the third region.

9. The semiconductor device according to claim 7, wherein
the second insulating portion includes a third insulating layer including the third region and a fourth insulating layer including the fourth region,
the fourth insulating layer is disposed between the third insulating layer and the third wiring, and
a density of the fourth insulating layer is lower than a density of the third insulating layer.

10. The semiconductor device according to claim 1, further comprising
a capacitor layer between the substrate and the oxide semiconductor layer, wherein
the capacitor layer includes a capacitor structure electrically connected to the oxide semiconductor layer.

11. The semiconductor device according to claim 1, wherein
the first insulating portion includes:
a cavity at a position farther from the second wiring than the first region; and
a third region between the first region and the cavity, wherein
a concentration of the first metal element in the third region is higher than the concentration of the first metal element in the first region, or a concentration of the second metal element in the third region is higher than the concentration of the second metal element in the first region.

12. The semiconductor device according to claim 7, wherein
the fourth region includes a portion in contact with the second region.

13. A semiconductor device comprising:
a substrate;
an oxide semiconductor layer that is spaced from the substrate in a first direction intersecting with a surface of the substrate and contains a first metal element and oxygen (O);
a first wiring opposed to a part of the oxide semiconductor layer;
a gate insulating film disposed between the oxide semiconductor layer and the first wiring;
a first conductive layer that is in contact with one end in the first direction of the oxide semiconductor layer and contains a second metal element and oxygen (O);
a second wiring electrically connected to the first conductive layer; and
a first insulating portion in contact with the second wiring, wherein
the first insulating portion includes:
a first region; and
a second region between the first region and the second wiring, and
a density of the second region is lower than a density of the first region.

14. The semiconductor device according to claim 13, wherein
the first insulating portion includes a first insulating layer including the first region and a second insulating layer including the second region,
the second insulating layer is disposed between the first insulating layer and the second wiring, and
a density of the second insulating layer is lower than a density of the first insulating layer.

15. The semiconductor device according to claim 14, wherein
the first insulating layer and the second insulating layer contain silicon (Si) and oxygen (O).

16. The semiconductor device according to claim 13, wherein
the first metal element is one element selected from a group consisting of indium (In), gallium (Ga), zinc (Zn), magnesium (Mg), aluminum (Al), manganese (Mn), tin (Sn), titanium (Ti), calcium (Ca), and cadmium (Cd).

17. The semiconductor device according to claim 13, wherein
the second metal element is one element selected from a group consisting of indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo).

18. The semiconductor device according to claim 13, further comprising:
a third wiring that is electrically connected to one end in the first direction of the second wiring and extends in a second direction intersecting with the first direction; and
a second insulating portion in contact with the third wiring, wherein
the second insulating portion includes:
a third region; and
a fourth region between the third region and the third wiring, and
a density of the fourth region is lower than a density of the third region.

19. The semiconductor device according to claim 18, wherein
the second insulating portion includes a third insulating layer including the third region and a fourth insulating layer including the fourth region,
the fourth insulating layer is disposed between the third insulating layer and the third wiring, and
a density of the fourth insulating layer is lower than a density of the third insulating layer.

20. The semiconductor device according to claim 13, further comprising
a capacitor layer between the substrate and the oxide semiconductor layer, wherein
the capacitor layer includes a capacitor structure electrically connected to the oxide semiconductor layer.
